(19) United States
(12) Patent Application Publication
(10) Pub. No.: US 2025/0054808 A1
(43) Pub. Date: Feb. 13, 2025

(54) SOI SUBSTRATE AND METHOD OF MANUFACTURING THE SAME

(71) Applicant: WUHAN XINXIN SEMICONDUCTOR MANUFACTURING CO., LTD., Wuhan (CN)

(72) Inventors: Guangjie XUE, Wuhan (CN); Le LI, Wuhan (CN); Jun ZHOU, Wuhan (CN)

(21) Appl. No.: 18/523,936

(22) Filed: Nov. 30, 2023

(30) Foreign Application Priority Data
Aug. 8, 2023 (CN) 202310995455.0

(51) Int. Cl. H01L 21/762; H01L 27/12

(52) U.S. Cl. CPC H01L 21/76243; H01L 27/1203

(57) ABSTRACT

A SOI substrate and a method of manufacturing a SOI substrate are provided. The method includes: providing a device wafer; wherein the device wafer includes a substrate, a buried oxide layer, and a semiconductor layer; the substrate has a first surface and a second surface opposite to the first surface; the buried oxide layer and the semiconductor layer are disposed sequentially on the first surface of the substrate; processing the substrate from the second surface of the substrate to sequentially form an insulating dielectric layer and an electrostatic adsorption layer; wherein a resistivity of the electrostatic adsorption layer is less than a resistivity of the substrate. The SOI substrate takes the electrostatic adsorption layer to perform electrostatic adsorption, difficulties of the SOI substrate performing the electrostatic adsorption are solved.

### CROSS REFERENCE TO RELATED APPLICATIONS

The present application claims the Chinese patent application No. 202310995455.0, filed on Aug. 8, 2023, and contents of which are incorporated herein by its entireties.

### TECHNICAL FIELD

The present disclosure relates to the field of semiconductors, and in particular to a SOI substrate and a method of manufacturing the SOI substrate.

### BACKGROUND

A semiconductor on insulator (SOI) substrate is a silicon-based semiconductor substrate having a unique three-layer structure of “Si/Insulator/Si”. For the SOI substrate, an insulating layer is introduced between a top silicon layer and a bottom substrate to achieve full dielectric isolation between a device and the bottom substrate.

In the SOI substrate having the three-layer structure, a surface layer is a thin single crystal silicon, configured to manufacture a device: a middle layer is insulating material dependent on a bulk silicon. It would be better if the insulating material is arranged as closed to the bulk silicon as possible. Therefore, the insulating layer is usually a silicon oxide layer, known as a buried oxide layer (BOX layer). By applying the SOI technology, dielectric isolation of the components in an integrated circuit may be achieved, a parasitic latch-up effect in a bulk silicon CMOS circuit is completely eliminated. Moreover, the integrated circuit made by applying the SOI technology may have a small parasitic capacitance, high integration density, a higher operating speed, a simple manufacturing process, and a small short-channel effect, and may especially be suitable for a low-voltage and low-power circuit.

However, a resistance of the SOI substrate in the art is getting higher and higher, and therefore, semiconductor devices may be manufactured more and more difficultly. Especially, the SOI substrate may have high resistivity and insulation properties, such that electrostatic adsorption of the SOI substrate may not be achieved easily.

### SUMMARY OF THE DISCLOSURE

The present disclosure provides a SOI substrate and a method of manufacturing the SOI substrate, aiming to solve the problem that the electrostatic adsorption of the SOI substrate in the prior art may be achieved difficultly.

The present disclosure provides a method of manufacturing a semiconductor-on-insulator (SOI) substrate, including: providing a device wafer: wherein the device wafer comprises a substrate, a buried oxide layer, and a semiconductor layer: the substrate has a first surface and a second surface opposite to the first surface; the buried oxide layer and the semiconductor layer are disposed sequentially on the first surface of the substrate: processing the substrate from the second surface of the substrate to sequentially form an insulating dielectric layer and an electrostatic adsorption layer: wherein a resistivity of the electrostatic adsorption layer is less than a resistivity of the substrate.

The present disclosure further provides a semiconductor-on-insulator (SOI) substrate, including:

a substrate, a buried oxide layer, and a semiconductor layer, which are laminated successively:

an insulating dielectric layer, laminated on a surface of the substrate away from the buried oxide layer; and

an electrostatic adsorption layer, laminated on a surface of the insulating dielectric layer away from the substrate, wherein a resistivity of the electrostatic adsorption layer is less than a resistivity of the substrate.

### BRIEF DESCRIPTION OF THE DRAWINGS

Various advantages and benefits will be illustrated clearly for any ordinary skilled person in the art by describing detailed description of the embodiments in the following. The accompanying drawings are used for the purpose of illustrating preferred embodiments and are not to limit the present disclosure. Moreover, in the accompanying drawings, same components are indicated by same reference numerals.

FIG. 1 is a flow chart of a method of manufacturing a SOI substrate according to an embodiment of the present disclosure.

FIG. 2 is a structural schematic view of a device wafer according to an embodiment of the present disclosure.

FIG. 3 is a structural schematic view of a protective layer formed on a surface of the device wafer according to an embodiment of the present disclosure.

FIG. 4 is a structural schematic view of oxygen ion implantation performed on a second surface of the substrate corresponding to the operation S2 of the method of manufacturing the SOI substrate according to an embodiment of the present disclosure.

FIG. 5 is a structural schematic view of an insulating dielectric layer formed in the substrate after a first annealing process.

FIG. 6 is a structural schematic view of the entirety of the portion of the substrate away from the insulating dielectric layer being converted to a electrostatic adsorption layer.

FIG. 7 is a schematic view of the structure shown in FIG. 6 after removing the protective laver.

FIG. 8 is a structural schematic view of an insulating dielectric layer formed on the second surface of the substrate corresponding to the operation S2 of the method of manufacturing the SOI substrate according to another embodiment of the present disclosure.

FIG. 9 is a structural schematic view of a semiconductor material layer formed on a surface of the insulating dielectric layer.

FIG. 10 is a structural schematic view of the semiconductor material layer being converted to the electrostatic adsorption layer.

FIG. 11 is a schematic view of the structure shown in FIG. 10 after removing the protective layer.

### REFERENCE NUMERALS IN THE DRAWINGS

1—substrate: 2—buried oxide layer: 3—semiconductor layer: 4—protective layer: 41—silicon nitride layer: 42—silicon oxide layer: 5—insulating dielectric layer: 51—oxygen ions; 6—electrostatic adsorption layer: 7—semiconductor material layer.

### DETAILED DESCRIPTION

Technical solutions in the embodiments of the present disclosure will be described clearly and completely in the following by referring to the accompanying drawings in the embodiments of the present disclosure. Apparently, the described embodiments show only a part of, but not all of, the embodiments of the present disclosure. All other embodiments, which are obtained by any ordinary skilled person in the art based on the embodiments in the present disclosure without making creative work, shall fall within the scope of the present disclosure.

Terms “first”, “second”, and “third” in the present disclosure are used for descriptive purposes only and shall not be interpreted as indicating or implying relative importance or implicitly specifying the number of technical features indicated. Therefore, a feature defined by “first”, “second”, and “third” may include at least one such feature either explicitly or implicitly. In the description of the present disclosure, “plurality” means at least two, such as two, three, and so on, unless otherwise expressly and specifically limited. All directional indications (such as up, down, left, right, front, rear, . . . ) in the embodiments of the present disclosure are used only to explain relative positional relationships and relative movements between components disposed in a particular attitude (the attitude as shown in the accompanying drawings). If the particular attitude changes, the directional indication changes accordingly. Furthermore, terms “include”, “have”, and any variations thereof, are intended to cover non-exclusive inclusion. For example, a process, a method, a system, a product or an apparatus including a series of operations or units is not limited to the listed operations or units, but optionally further includes operations or units that are not listed, or optionally includes other operations or units that are inherently included in the process, the method, the product or the apparatus.

“Embodiments” herein implies that particular features, structures, or characteristics described in an embodiment may be included in at least one embodiment of the present disclosure. Presence of the term at various sections in the specification does not necessarily refer to one same embodiment, nor a separate or alternative embodiment that is mutually exclusive of other embodiments. It is understood by any ordinary skilled person in the art, both explicitly and implicitly, that the embodiments described herein may be combined with other embodiments.

A radio frequency (RF) device is usually required to operate at a relatively low level of harmonics. In the art, a RF front-end device is required to operate at the harmonics of less than-40 dB. For an RF switch of the RF front-end devices, SOI substrates of a silicon-on-insulator process occupy most of the market. As requirements for the product become higher, requirements for the harmonics are higher. Harmonics brought by the SOI substrate cannot be avoided, but may only be reduced. The silicon-on-insulator substrate also reaches a new generation. The resistivity of the substrate is increasingly larger, and even a trap-rich layer is introduced. In addition, a resistance of the SOI substrate is increasingly larger, and accordingly, it is increasingly difficult to manufacture semiconductor devices. Especially, the SOI substrate may have high resistivity and insulation properties, such that electrostatic adsorption of the SOI substrate may not be achieved easily.

Therefore, the present disclosure provides an SOI substrate and a method of manufacturing the SOI substrate. By arranging a insulating dielectric layer and a electrostatic adsorption layer having a low resistivity on a side where a second surface of the substrate is located, the SOI substrate may take the electrostatic adsorption layer to perform electrostatic adsorption, such that difficulties in the substrate performing electrostatic adsorption may be solved. In addition, by arranging the insulating dielectric layer between the electrostatic adsorption layer and the substrate, an influence on the substrate caused by the subsequent processes may be reduced, the performance of the substrate may not be changed.

The present disclosure is to be described in detail below by referring to the accompanying drawings and embodiments.

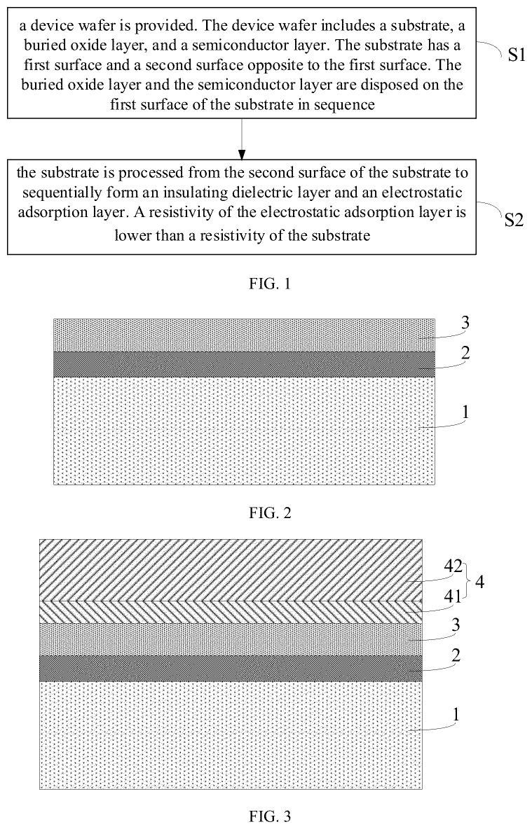

FIG. 1 is a flow chart of a method of manufacturing a SOI substrate according to an embodiment of the present disclosure, and FIG. 2 is a structural schematic view of a device wafer according to an embodiment of the present disclosure. In the embodiment, a method of manufacturing a SOI substrate is provided, and the method includes the following operations.

In an operation S1, a device wafer is provided. The device wafer includes a substrate, a buried oxide layer, and a semiconductor layer. The substrate has a first surface and a second surface opposite to the first surface. The buried oxide layer and the semiconductor layer are disposed on the first surface of the substrate in sequence.

The substrate 1 may be silicon having a high resistivity of greater than 7000 Ω·cm. A thickness of the substrate 1 may be 500 um-1000 um: such as, 500 um, 600 um, 700 um, 800 um, 900 um, and so on. The semiconductor layer 3 may be silicon having a low resistivity. The buried oxide layer 2 is disposed between the substrate 1 and the semiconductor layer 3. The buried oxide layer 2 may be silicon oxide or silicon oxynitride.

In some embodiments, a polycrystalline silicon layer (not shown in the drawings) is further disposed between the substrate 1 and the buried oxide layer 2. The polycrystalline silicon layer serves as a trap-rich layer to trap parasitic charges that are free in the buried oxide layer and the substrate, ensuring that the substrate I has a significantly high resistivity.

FIG. 3 is a structural schematic view of a protective layer formed on a surface of the device wafer according to an embodiment of the present disclosure. After the operation S1 and before the operation S2, the method further includes the following.

In an operation A, a protective layer 4 is formed on a surface of the semiconductor layer 3 away from the buried oxide layer 2.

In the above, since the protective layer 4 is formed, before the operation S2, on the surface of the semiconductor layer 3 away from the buried oxide layer 2, the protective layer 4 protects the surface of the semiconductor layer 3 away from the buried oxide layer 2, such that, while the operation S2 is being performed, the surface of the semiconductor layer 3 away from the buried oxide layer 2 may be prevented from being damaged.

In some embodiments, when the protective layer 4 is a silicon nitride layer 41, due to the silicon nitride having a higher stress, the device wafer may be bent when the silicon nitride layer 41 has a certain thickness. When the protective layer 4 is a silicon oxide layer 42, the silicon oxide layer 42 is relatively soft, and the silicon oxide layer 42 may not effectively protect the surface of the semiconductor layer 3. Therefore, in an embodiment, the protective layer 4 specifically includes the silicon nitride layer 41 and the silicon oxide layer 42 that are stacked with each other. In the present embodiment, as shown in FIG. 3, the operation A specifically includes the following.

In an operation m, the silicon nitride layer 41 is formed on the surface of the semiconductor layer 3 away from the buried oxide layer 2.

In an operation n, the silicon oxide layer 42 is formed on a surface of the silicon nitride layer 41 away from the semiconductor layer 3.

In this way, the silicon nitride layer 41 may effectively protect the surface of the semiconductor layer 3 away from the substrate 1; and the silicon oxide layer 42 may release the stress of the silicon nitride layer 41. Therefore, a probability that the device wafer being bent caused by the stress of the silicon nitride layer 41 may be reduced.

The silicon nitride layer 41 and the silicon oxide layer 42 may be formed by deposition. Each of a thickness of the silicon nitride layer 41 and a thickness of the silicon oxide layer 42 is greater than 1000 A, such that the silicon nitride layer 41 and the silicon oxide layer 42 may better protect the surface of the semiconductor layer 3.

In the following embodiments, forming the protective layer 4 on the surface of the device wafer will be described as an example. After the operation A, the device wafer is flipped over, such that the protective layer 4 is facing downward (the downward orientation shown in the accompanying drawings) and contacts a machine that performs the operation S2. Subsequently, the operation S2 is performed.

In the operation S2, the substrate is processed from the second surface of the substrate to sequentially form an insulating dielectric layer and an electrostatic adsorption layer. A resistivity of the electrostatic adsorption layer is lower than a resistivity of the substrate 1.

The insulating dielectric layer 5 may be silicon oxide. The resistivity of the electrostatic adsorption layer 6 may specifically be less than 200 Ω·cm: such as 500 Ω·cm, 800 Ω·cm, 900 Ω·cm, 1000 Ω·cm, 1100 Ω·cm, 1200 Ω·cm, or 1300 Ω·cm, and so on. In some embodiments, the resistivity of the electrostatic adsorption layer 6 may specifically be less than 1000 Ω·cm.

In the above, by forming the insulating dielectric layer 5 and the electrostatic adsorption layer 6 having the low resistivity on the side where the second surface of the substrate I is located, the SOI substrate may take the electrostatic adsorption layer 6 to perform electrostatic adsorption, such that difficulties in the substrate 1 performing electrostatic adsorption may be solved. In addition, by arranging the insulating dielectric layer 5 between the electrostatic adsorption layer 6 and the substrate 1, the subsequent processes may not affect the substrate 1. For example, in a flow-through process, a certain H-containing process performed on the second surface of the substrate 1 may not affect high-resistance performance of the substrate 1 of the device wafer, and therefore, the performance of the substrate 1 may not be impacted.

In some embodiments, as shown in FIG. 4 to FIG. 6, FIG. 4 to FIG. 6 are structural schematic views corresponding to the operation S2 of the method of manufacturing the SOI substrate according to an embodiment of the present disclosure. The operation S2 specifically includes the following.

In an operation S21a, oxygen ion 51 implantation is performed on the second surface of the substrate 1, and a first annealing process is performed to convert a portion of the substrate 1 into the insulating dielectric layer 5.

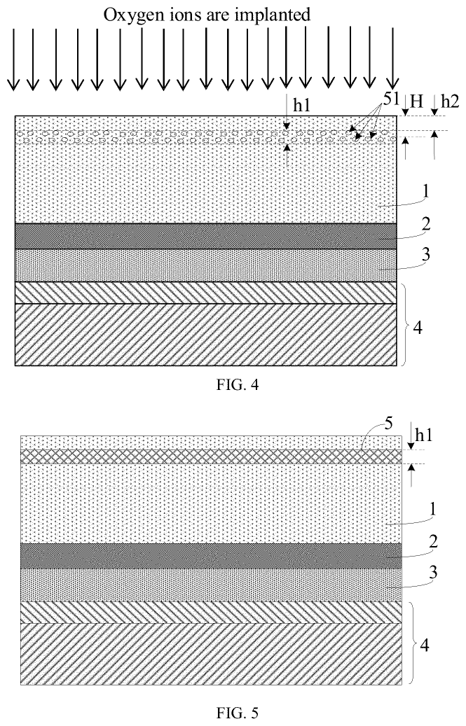

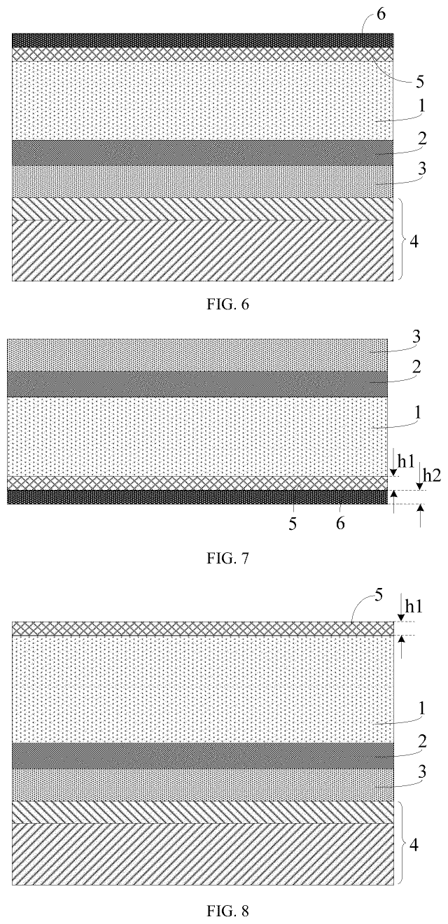

FIG. 4 shows a schematic view of the oxygen ion implantation performed on the second surface of the substrate; and FIG. 5 shows a structural schematic view of the product shown in FIG. 4, after the first annealing process is performed. The oxygen ions 51 are implanted to reach a depth H of 5 um to 10 um: such as, 5 um, 6 um, 7 um, 8 um, 9 um, 10 um. By controlling the implantation depth of the oxygen ions 51, a thickness of a portion of the substrate I away from the insulating dielectric layer 5 that will be subsequently converted into the electrostatic adsorption layer 6 may be controlled. Therefore, the resistivity of the electrostatic adsorption layer 6 and an electrostatic adsorption capacity of the electrostatic adsorption layer 6 may meet requirements.

Specifically, the oxygen ions 51 may be implanted for once or in a plurality of times, and the oxygen ions 51 are implanted to reach the vertical depth h1 of greater than 50 nm: such as, 60 nm, 80 nm, 100 nm, 150 nm, and so on. In this way, the insulating dielectric layer 5 having a thickness h1 of greater than 50 nm may be formed after the annealing process. Therefore, the insulating dielectric layer 5 having the above thickness may reduce the influence on the performance of the substrate 1 of the device wafer caused by the subsequent process.

In addition, since the oxygen ions 51 are in a free state after being implanted into the substrate 1, a dense insulating dielectric layer 5 cannot be formed. Therefore, after the oxygen ions 51 are implanted, a first high-temperature annealing process is further performed. In this way, the oxygen ions 51 may react with the substrate 1, such that the dense insulating dielectric layer 5 may be formed. Specifically, the insulating dielectric layer 5 may be a silicon oxide layer, such as a silicon dioxide layer.

Specifically, a temperature of the first high-temperature annealing process is greater than 700° C., such as 750° C., 800° C., 900° C. or 1000° C. In some embodiments, a furnace tube may be used or a rapid thermal annealing (RTA) may be performed to achieve the first high-temperature annealing process. The present disclosure does not limit how to achieve the first high-temperature annealing process, as long as a total heat is sufficient to enable the silicon oxide layer to have the thickness of greater than 50 nm.

In an operation S22a, another ion implantation is performed on the second surface of the substrate 1, and a second annealing process is performed to convert the entirety of the portion of the substrate I away from the insulating dielectric layer 5 into the electrostatic adsorption layer 6.

FIG. 6 shows a structural schematic view of the entirety of the portion of the substrate away from the insulating dielectric layer being converted to the electrostatic adsorption layer. An implantation depth of the ions is less than an implantation depth of the oxygen ions 51. The ions include at least one type of following ions: boron (B) ions, fluorine (F) ions, phosphorus (P) ions, and arsenic (As) ions. A dose of the ions implanted into the substrate is greater than 1*1015/cm3. In this way, it is ensured that the entirety of the portion of the substrate I away from the insulating dielectric layer 5 is converted into the electrostatic adsorption layer 6, and the resistivity of the formed electrostatic adsorption layer 6 is less than the resistivity of the substrate 1. The electrostatic adsorption layer 6 formed in this way is single crystalline silicon.

The resistivity of the substrate I may not be reduced if the ions are not activated after the ions are implanted into the substrate 1. Therefore, after the ions are implanted, the second annealing process is performed to activate the ions, such that the resistance of the substrate 1 of the device wafer is reduced, and the electrostatic adsorption layer 6 having the low resistance is formed.

The second annealing process may be any common annealing process in the industry such as the RTA/Spike (spike) annealing process.

Specifically, the electrostatic adsorption layer 6 has a thickness of

$$h 2 = H - \frac{h 1}{2}$$

to ensure that the electrostatic adsorption layer 6 has a certain electrostatic adsorption capacity.

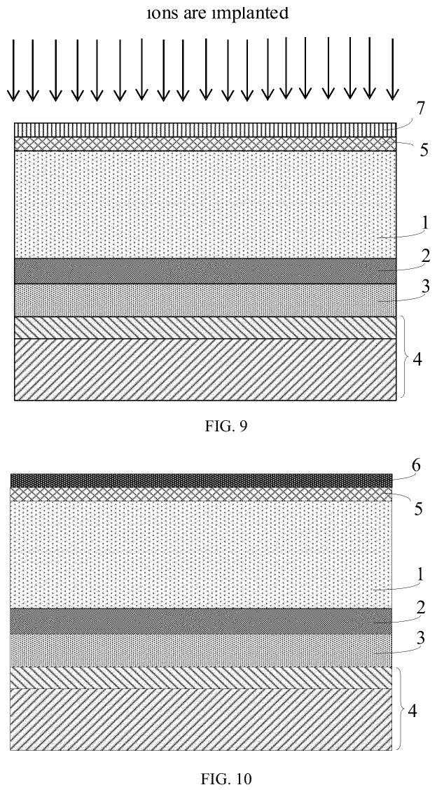

FIG. 7 is a structural schematic view of the structure shown in FIG. 6 after removing the protective layer. After the operation S22a, the method further includes: removing the protective layer 4. Subsequently, a device manufacturing process is performed.

Specifically, the device wafer is flipped back, such that a surface of the device wafer on which the protective layer 4 is arranged is facing upward. Further, the protective layer 4 is removed to obtain the SOI substrate. Specifically, chemical mechanical polishing (CMP) or etching process may be performed to remove the protective layer 4. It will be appreciated that in the present embodiment, a thickness of the substrate 1 in the finally-formed SOI substrate is less than the thickness of the substrate 1 in the initially-provided device wafer. Other structures and functions of the substrate 1 in the finally-formed SOI substrate are the same as the those of the substrate in the device wafer.

In another embodiment, as shown in FIG. 8 to FIG. 10, FIG. 8 to FIG. 10 are structural schematic views corresponding to the operation S2 of the method of manufacturing the SOI substrate according to another embodiment of the present disclosure. Unlike the above embodiment, the operation S2 in the present embodiment specifically includes the following.

In an operation S21b, an insulating material is arranged on the second surface of the substrate 1 to form the insulating dielectric layer 5.

FIG. 8 shows a schematic view of a structure having the insulating dielectric layer formed on the second surface of the substrate. Specifically, the insulating material may be arranged, by a thermal oxidation process or a deposition process, to form the insulating dielectric layer 5. The insulating material may be silicon oxide, such as silicon dioxide. The thickness h1 of the insulating dielectric layer 5 may be greater than 50 nm.

In an operation S22b, the electrostatic adsorption layer 6 is formed on a surface of the insulating dielectric layer 5 away from the substrate 1. FIG. 9 shows a schematic view of a structure of arranging a semiconductor material layer on a surface of the insulating dielectric layer. In an embodiment, the operation S22b includes the following. The semiconductor material layer 7 is formed on a surface of the insulating dielectric layer 5 away from the substrate 1. The semiconductor material layer may be polycrystalline silicon. The polycrystalline silicon may be arranged by performing a furnace-tube deposition process or by epitaxial growth.

After forming the semiconductor material layer 7, ion implantation is performed on the semiconductor material layer 7, and a third annealing process is performed to convert the entirety of the semiconductor material layer 7 into the electrostatic adsorption layer 6. FIG. 10 shows a schematic structure of the semiconductor material layer in the structure shown in FIG. 9 being converted to the electrostatic adsorption layer. The implanted ions include at least one type of following ions: boron (B) ions, fluorine (F) ions, phosphorus (P) ions, and arsenic (As) ions. A dose of the ions implanted into the semiconductor material layer 7 is greater than 1*1015/cm3. In this way, it is ensured that the entirety of the semiconductor material layer 7 is converted into the electrostatic adsorption layer 6, and the resistivity of the formed electrostatic adsorption layer 6 is less than the resistivity of the substrate 1. The process in the present embodiment is similar to that of the operation S22a in the above, which may be referred to the above.

In another embodiment, the operation S22b includes the following. The semiconductor material layer 7 is formed on the surface of the insulating dielectric layer 5 away from the substrate 1; and ion doping is performed, while the semiconductor material layer 7 is being formed, to form the electrostatic adsorption layer 6.

The electrostatic adsorption layer 6 is polycrystalline silicon having a resistivity of less than 2000 Ω·cm. For example, the resistivity of the electrostatic adsorption layer 6 is 500 Ω·cm, 800 Ω·cm, 900 Ω·cm, 1000 Ω·cm, 1100 Ω·cm, 1200 Ω·cm, 1300 Ω·cm, and so on. In some embodiments, the resistivity of the electrostatic adsorption layer 6 may specifically be less than 1000 Ω·cm.

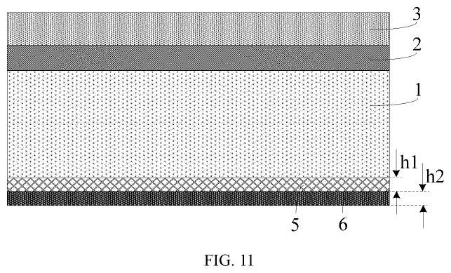

FIG. 11 is a structural schematic view of the structure shown in FIG. 10 after removing the protective layer. After the operation S22b, the method further includes: removing the protective layer 4.

Specifically, the device wafer is flipped back, such that the surface of the device wafer on which the protective layer 4 is arranged is facing upwardly. Subsequently, the protective layer 4 is removed to obtain another SOI substrate. Specifically, the protective layer 4 may be removed by performing chemical mechanical polishing (CMP) or etching process.

According to the method of manufacturing the SOI substrate in the present embodiment, the device wafer is provided. The device wafer includes the substrate 1, the buried oxide layer 2, and the semiconductor layer 3. The substrate I has the first surface and the second surface opposite to the first surface. The buried oxide layer 2 and the semiconductor layer 3 are arranged on the first surface of the substrate 1 in sequence. The substrate 1 is processed from the second surface of the substrate I to form the insulating dielectric layer 5 and the electrostatic adsorption layer 6 successively. The resistivity of the electrostatic adsorption layer 6 is less than the resistivity of the substrate 1. By forming the insulating medium layer 5 and the electrostatic adsorption layer 6 having the low resistivity on the side where the second surface of the substrate I is located, the SOI substrate may take the electrostatic adsorption layer 6 to perform the electrostatic adsorption, difficulties in the substrate performing electrostatic adsorption may be solved, the process difficulties may be reduced, and the harmonics may be improved. In addition, by arranging the insulating dielectric layer 5 between the electrostatic adsorption layer 6 and the substrate 1, an influence on the substrate 1 caused by the subsequent processes may be reduced, the performance of the substrate I may not be changed.

As shown in FIG. 7 and FIG. 11, in the present embodiment, the SOI substrate is provided and may be obtained by performing the above-described method of manufacturing the SOI substrate. The SOI substrate includes: the substrate 1, the buried oxide layer 2, the semiconductor layer 3, the insulating dielectric layer 5, and the electrostatic adsorption layer 6.

The substrate I may be high-resistivity silicon. The resistivity of the substrate I may be greater than 7000 Ω·cm. The thickness of the substrate 1 may be 500 um-1000 um; such as, 500 um, 600 um, 700 um, 800 um, 900 um, and so on. The semiconductor layer 3 may be low-resistivity silicon. The buried oxide layer 2 is disposed between the substrate 1 and the semiconductor layer 3. The buried oxide layer 2 may be silicon oxide or silicon oxynitride.

The insulating dielectric layer 5 is laminated on the surface of the substrate 1 away from the buried oxide layer 2 and is configured to isolate the substrate 1 from the electrostatic adsorption layer 6. The insulating dielectric layer 5 may be a silicon oxide layer, such as a silicon dioxide layer. The thickness h1 of the insulating dielectric layer 5 is greater than 50 nm, such as 55 nm, 60 nm, 70 nm, and so on. The insulating dielectric layer 5 having the above thickness may reduce the influence on the performance of the substrate 1 of the device wafer caused by other processes.

The electrostatic adsorption layer 6 is laminated on the surface of the insulating dielectric layer 5 away from the substrate 1. The resistivity of the electrostatic adsorption layer 6 is less than the resistivity of the substrate 1. In this way, the electrostatic adsorption layer 6 may perform the electrostatic adsorption, such that difficulties in the SOI substrate performing electrostatic adsorption may be solved. The resistivity of the electrostatic adsorption layer 6 is specifically less than 2000 Ω·cm. For example, the resistivity of the electrostatic adsorption layer 6 is 500 Ω·cm, 800 Ω·cm, 900 Ω·cm, 1000 Ω·cm, 1100 Ω·cm, 1200 Ω·cm, 1300 Ω·cm, and so on. In some embodiments, the resistivity of the electrostatic adsorption layer 6 is specifically less than 1000 Ω·cm.

Specifically, the electrostatic adsorption layer 6 may be polycrystalline silicon or single crystal silicon.

Specifically, the electrostatic adsorption layer 6 includes the semiconductor material layer and ions dispersed in the semiconductor material layer. The ions may be uniformly dispersed in the semiconductor material layer. The semiconductor material may be silicon. The ions include at least one type of following ions: boron (B) ions, fluorine (F) ions, phosphorus (P) ions, and arsenic (As) ions.

In some embodiments, the SOI substrate further includes a polycrystalline silicon layer (not shown in the figures), the polycrystalline silicon layer is disposed between the substrate I and the buried oxide layer 2. The polycrystalline silicon layer serves as the trap-rich layer to trap the parasitic charges that are free in the buried oxide layer and the substrate, ensuring that the substrate 1 has a very high resistivity.

The SOI substrate provided in the present embodiment includes the device wafer, the insulating dielectric layer 5, and the electrostatic adsorption layer 6. The device wafer includes the substrate 1, the buried oxide layer 2, and the semiconductor layer 3 that are laminated in sequence. The insulating dielectric layer 5 is laminated on the surface of the substrate I away from the buried oxide layer 2. The electrostatic adsorption layer 6 is laminated on the surface of the insulating dielectric layer 5 away from the substrate 1. The resistivity of the electrostatic adsorption layer 6 is less than that of the substrate 1. The SOI substrate takes the electrostatic adsorption layer 6 to perform the electrostatic adsorption, such that difficulties in the SOI substrate performing electrostatic adsorption may be solved. In addition, the high-resistance performance of the substrate 1 of the device wafer is not changed.

The above shows only embodiments of the present disclosure, but does not limit the scope of the present disclosure. Any equivalent structure or equivalent process transformations made based on the contents of the specification and the accompanying drawings of the present disclosure, applied directly or indirectly in other related technical fields, shall be similarly included in the scope of the present disclosure.

What is claimed is:

1. A method of manufacturing a semiconductor-on-insulator (SOI) substrate, comprising:
providing a device wafer; wherein the device wafer comprises a substrate, a buried oxide layer, and a semiconductor layer; the substrate has a first surface and a second surface opposite to the first surface: the buried oxide layer and the semiconductor layer are disposed sequentially on the first surface of the substrate; and
processing the substrate from the second surface of the substrate to sequentially form an insulating dielectric layer and an electrostatic adsorption layer: wherein a resistivity of the electrostatic adsorption layer is less than a resistivity of the substrate.

2. The method according to claim 1, wherein the processing the substrate from the second surface of the substrate to sequentially form an insulating dielectric layer and an electrostatic adsorption layer, comprises:
implanting oxygen ions into the substrate from the second surface and performing a first annealing process to convert a portion of the substrate into the insulating dielectric layer; and
implanting ions into the substrate from the second surface and performing a second annealing process to convert the entirety of a portion of the substrate away from the insulating dielectric layer into the electrostatic adsorption layer.

3. The method according to claim 1, wherein the resistivity of the substrate is greater than 7000 Ω·cm; the resistivity of the electrostatic adsorption layer is less than 2000 Ω·cm.

4. The method according to claim 1, wherein the processing the substrate from the second surface of the substrate to sequentially form an insulating dielectric layer and an electrostatic adsorption layer, comprises:
forming an insulating material on the second surface of the substrate to form the insulating dielectric layer; and
forming the electrostatic adsorption layer on a surface of the insulating dielectric layer away from the substrate.

5. The method according to claim 4, wherein the forming the electrostatic adsorption layer, comprises:
forming a semiconductor material layer on the surface of the insulating dielectric layer away from the substrate, implanting ions into the semiconductor material layer, and performing a third annealing process to convert the entirety of the semiconductor material layer into the electrostatic adsorption layer.

6. The method according to claim 4, wherein the forming the electrostatic adsorption layer, comprises:
forming a semiconductor material layer on the surface of the insulating dielectric layer away from the substrate; and performing, while the semiconductor material layer is being formed, ion doping to form the electrostatic adsorption layer.

7. The method according to claim 1, wherein, before the processing the substrate from the second surface of the substrate to sequentially form an insulating dielectric layer and an electrostatic adsorption layer, the method further comprises: forming a protective layer on a surface of the semiconductor layer away from the buried oxide layer; and
after the processing the substrate from the second surface of the substrate to sequentially form an insulating dielectric layer and an electrostatic adsorption layer, the method further comprises: removing the protective layer.

8. The method according to claim 7, wherein the forming a protective layer on a surface of the semiconductor layer away from the buried oxide layer, comprises:
forming a silicon nitride layer on the surface of the semiconductor layer away from the buried oxide layer; and
forming a silicon oxide layer on a surface of the silicon nitride layer away from the semiconductor layer.

9. The method according to claim 1, wherein
the insulating dielectric layer has a thickness greater than 50 nm.

10. The method according to claim 1, wherein, a polycrystalline silicon layer is disposed between the substrate and the buried oxide layer and serves as a trap-rich layer to trap parasitic charges that are free in the buried oxide layer and the substrate.

11. The method according to claim 2, wherein the oxygen ions are implanted to reach a depth of H, the insulating dielectric layer has a thickness of h1, and the electrostatic adsorption layer has a thickness of h2, and the H, the h1, and the h2 meet following equation:
$$h 2 = H - \frac{h 1}{2} .$$

12. A semiconductor-on-insulator (SOI) substrate, comprising:
a substrate, a buried oxide layer, and a semiconductor layer, which are laminated successively;
an insulating dielectric layer, laminated on a surface of the substrate away from the buried oxide layer; and
an electrostatic adsorption layer, laminated on a surface of the insulating dielectric layer away from the substrate, wherein a resistivity of the electrostatic adsorption layer is less than a resistivity of the substrate.

13. The SOI substrate according to claim 12, wherein the insulating dielectric layer has a thickness of greater than 50 nm.

14. The SOI substrate according to claim 12, wherein, the substrate has a resistivity of greater than 7000 Ω·cm; the electrostatic adsorption layer has a resistivity of less than 2000 Ω·cm.

15. The SOI substrate according to claim 12, wherein the electrostatic adsorption layer is polycrystalline silicon or single crystalline silicon; or the insulating dielectric layer is silicon oxide.

16. The SOI substrate according to claim 12, further comprising a polycrystalline silicon layer disposed between the substrate and the buried oxide layer.
